(19) United States
(12) Patent Application Publication
(10) Pub. No.: US 2022/0238347 A1
(43) Pub. Date: Jul. 28, 2022

(54) FORMING OF HIGH ASPECT RATIO FEATURES AND METHOD FOR FABRICATING SEMICONDUCTOR DEVICE USING THE HIGH ASPECT RATIO FEATURES

(71) Applicant: SK hynix Inc., Icheon-si Gyeonggi-do (KR)

(72) Inventor: Jang Won KIM, Icheon-si Gyeonggi-do (KR)

(73) Assignee: SK hynix Inc., Icheon-si Gyeonggi-do (KR)

(21) Appl. No.: 17/375,282

(22) Filed: Jul. 14, 2021

(30) Foreign Application Priority Data
Jan. 28, 2021 (KR) 10-2021-0012332

(51) Int. Cl. H01L 21/311; H01L 27/11556; H01L 27/11582

(52) U.S. Cl. CPC H01L 21/31116; H01L 27/11582; H01L 27/11556; H01L 21/31144

(57) ABSTRACT

A method for fabricating a semiconductor includes: forming an etch target layer on a substrate, wherein the etch target layer includes an alternating stack layer and a sacrificial stack layer on the alternating stack layer, and wherein the sacrificial stack layer includes the same material as the alternating stack layer; forming a hard mask pattern on the sacrificial stack layer; etching the etch target layer using the hard mask pattern as an etch barrier to form a plurality of initial high aspect ratio features, the initial high aspect ratio features penetrating through the etch target layer; and removing the hard mask pattern and the sacrificial stack layer to form a plurality of high aspect ratio features.

### CROSS-REFERENCE TO RELATED APPLICATIONS

The present application claims priority to Korean Patent Application No. 10-2021-0012332, filed on Jan. 28, 2021, which is herein incorporated by reference in its entirety.

### BACKGROUND

### 1. Technical Field

The present disclosure relates to a semiconductor device, and more particularly, to a semiconductor device including high aspect ratio features.

### 2. Related Art

For fabricating a semiconductor device, etching is required for a three-dimensional structure or a high aspect ratio feature. Etching for a high aspect ratio feature is being performed, for example, for fabricating a vertical semiconductor device.

### SUMMARY

According to an embodiment, a method for fabricating a semiconductor device may include forming an etch target layer on a substrate, wherein the etch target layer includes an alternating stack layer and a sacrificial stack layer on the alternating stack layer, and wherein the sacrificial stack layer includes the same material as the alternating stack layer; forming a hard mask pattern on the sacrificial stack layer; etching the etch target layer using the hard mask pattern as an etch barrier to form a plurality of initial high aspect ratio features, the initial high aspect ratio features penetrating through the etch target layer; and removing the hard mask pattern and the sacrificial stack layer to form a plurality of high aspect ratio features.

According to an embodiment, a method for fabricating a semiconductor device may include forming an alternating stack layer by alternately stacking first oxide layers and first nitride layers on a substrate; forming a sacrificial stack layer by alternately stacking second oxide layers and second nitride layers on the alternating stack; forming an amorphous carbon layer pattern on the sacrificial stack layer; etching the sacrificial stack layer and the alternating stack layer using the amorphous carbon layer pattern as an etch barrier to form a plurality of initial high aspect ratio features, the initial high aspect ratio features penetrating through the sacrificial stack layer and the alternating stack layer; removing the amorphous carbon pattern and the sacrificial stack layer to form a plurality of high aspect ratio features; forming a vertical channel structure filling the high aspect ratio features; and replacing the first nitride layers of the alternating stack layer with gate electrodes.

According to an embodiment, a method for fabricating a semiconductor device may include forming an etch stop layer on a substrate; forming an alternating stack layer by alternately stacking first oxide layers and first nitride layers on the etch stop layer; forming a sacrificial stack layer by alternately stacking second oxide layers and second nitride layers on the alternating stack layer; forming an amorphous carbon layer pattern on the sacrificial stack layer; etching the sacrificial stack layer and the alternating stack layer using the amorphous carbon layer pattern as an etch barrier to form a plurality of initial high aspect ratio features, the initial high aspect ratio features penetrating through the sacrificial stack layer and the alternating stack layer; removing the amorphous carbon layer pattern and the sacrificial stack layer to form a plurality of high aspect ratio features; forming a storage node in each of the high aspect ratio features; forming a multi-level supporter by selectively etching the first nitride layers, the multi-level supporter supporting the storage node; and removing the first nitride layers.

According to an embodiment, a hard mask for forming through dry etching a high aspect ratio in a stack film, in which first silicon oxides and first silicon nitrides are alternately stacked, the hard mask comprising: a carbon-free hard mask, in which second silicon oxides and second silicon nitrides are alternately stacked; and a carbon-containing hard mask on the carbon-free hard mask.

### BRIEF DESCRIPTION OF THE DRAWINGS

FIGS. 1, 2, 3, 4, 5, 6, 7, and 8 are diagrams illustrating a method for fabricating a semiconductor device in accordance with an embodiment of the present disclosure.

FIGS. 9, 10, 11, 12, 13, 14, and 15 are diagrams illustrating a method for fabricating a semiconductor device in accordance with an embodiment of the present disclosure.

FIGS. 16, 17, 18, 19, 20, 21, and 22 are diagrams illustrating a method for fabricating a semiconductor device in accordance with an embodiment of the present disclosure.

### DETAILED DESCRIPTION

Examples of embodiments described herein will be described with reference to cross-sectional views, plane views and block diagrams, which are ideal schematic views of the present invention. Therefore, the structures of the drawings may be modified by fabricating technology and/or tolerances. The embodiments of the present disclosure are not limited to the specific structures shown in the drawings, but include any changes in the structures that may be produced according to the fabricating process. Also, any regions and shapes of regions illustrated in the drawings have schematic views, are intended to illustrate specific examples of structures of regions of the various elements, and are not intended to limit the scope of the embodiments.

Same reference numerals refer to same elements throughout the specification. Thus, even though a reference numeral is not mentioned or described with reference to a drawing, the reference numeral may be mentioned or described with reference to another drawing. In addition, even though a reference numeral is not shown in a drawing, it may be mentioned or described with reference to another drawing. Various examples of the embodiments are described herein with reference to cross-sectional illustrations that are schematic illustrations of the various examples of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but may be to include deviations in shapes that result, for example, from manufacturing. In the drawings, lengths and sizes of layers and regions may be exaggerated for clarity. It is also understood that when a layer is referred to as being “on” another layer or substrate, it can be directly on the other or substrate, or intervening layers may also be present. It will be understood that although the terms first, second, third etc. may be used herein to describe various elements, these elements should not be limited by these terms. These terms are only used to distinguish one element from another element, but not used to define only the element itself or to mean a particular sequence.

Embodiments of the present disclosure may provide a method for fabricating a high aspect ratio feature with an improved open margin.

Embodiments of the present disclosure provides a method for fabricating a semiconductor device capable of improving an open margin of a high aspect ratio feature.

The present disclosure may use the uppermost material of an etch target layer as a hard mask during an etching process of a high aspect ratio. Accordingly, the open margin of the high aspect ratio feature may be improved, thereby forming the high aspect ratio feature of which a bowing-free and bottom width are secured.

In the following embodiments, the high aspect ratio features may include a three-dimensional structure. The high aspect ratio features may include vertical structures, horizontal structures, or a combination thereof. The high aspect ratio features may be referred to as contact holes, trenches, recesses, or openings. The ratio of the depth to the width of the high aspect ratio features may be at least 10:1 or greater.

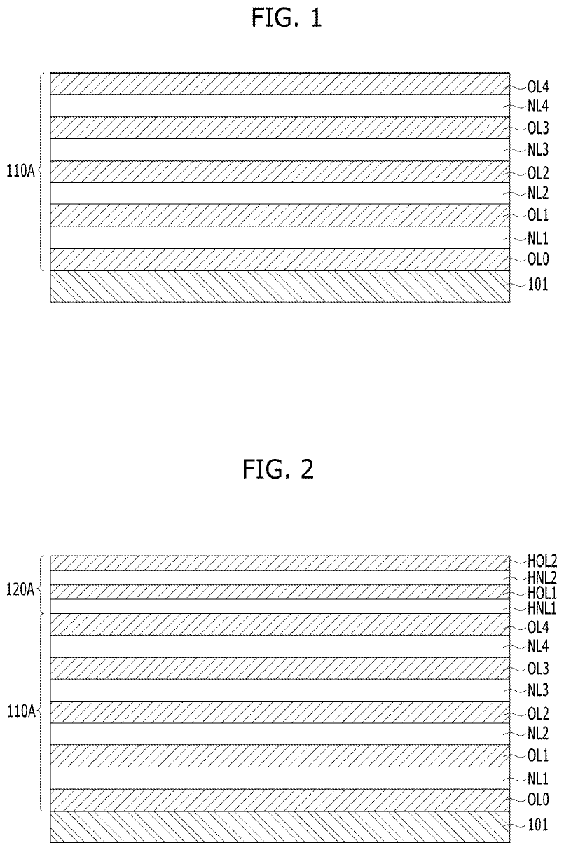

FIGS. 1 to 8 are diagrams illustrating a method for fabricating a semiconductor device in accordance with an embodiment of the present disclosure.

As shown in FIG. 1, an alternating stack layer 110A may be formed on a substrate 101, and the alternating stack layer 110A may be a stack of a plurality of layers formed of different materials. The substrate 101 may be a material suitable for semiconductor processing. The substrate 101 may include a semiconductor substrate. For example, the substrate 101 may include silicon substrate, single crystal silicon substrate, polysilicon substrate, amorphous silicon substrate, silicon germanium substrate, monocrystalline silicon germanium substrate, polycrystalline silicon germanium substrate, carbon doped silicon substrate, a combination thereof, or a multilayer composed thereof. The substrate 101 may also include other semiconductor materials such as germanium. The substrate 101 may include a group III/V semiconductor substrate, for example, a compound semiconductor substrate such as GaAs. The substrate 101 may include a silicon on insulator (SOI) substrate. Although not shown, a peripheral circuit may be formed between the substrate 101 and the alternating stack layer 110A. The peripheral circuit may be formed using, for example, a well-known method of forming a semiconductor circuit. After the peripheral circuit is formed, the alternating stack layer 110A may be formed.

The alternating stacked layer 110A is a stacked body and may include insulating layers OL0 to OL4 and sacrificial layers NL1 to NL4. The insulating layers OL0 to OL4 may include an insulating material, and the sacrificial layers NL1 to NL4 may include a sacrificial material. Here, the ‘sacrificial material’ may refer to a material that is removed in a subsequent process. The insulating layers OL0 to OL4 may include at least any one insulating material selected from among silicon oxide, silicon nitride, silicon oxynitride, spin-on insulating material (SOD), insulating metal oxide, silicate, and insulating metal oxynitride. In an embodiment, a layer including a nitride may be referred to as a nitride layer or and a layer including an oxide may be referred to as an oxide layer. For example, an alternating stack layer 110A may be formed by alternately stacking first oxide layers (i.e., OL0 to OL4) and first nitride layers (i.e., NL1 to NL4) and a sacrificial stack layer may be formed by alternately stacking second oxide layers (i.e., HOL1 to HOL2) and second nitride layers (i.e., HNL1 to HNL2).

The sacrificial layers NL1 to NL4 may include a sacrificial material that may be selectively removed with respect to the insulating layers OL0 to OL4. Here, removal of the sacrificial layers NL1 to NL4 may be selective with respect to the insulating layers OL0 to OL4. A ratio of removal speed of the sacrificial layers NL1 to NL4 and the removal speed of the insulating layers OL0 to OL4 may be referred to as a selectivity of a removal process of the sacrificial layers NL1 to NL4 with respect to the insulating layers OL0 to OL4.

The sacrificial layers NL1 to NL4 may include an insulating material. The sacrificial layers NL1 to NL4 may be replaced with a conductive material in a subsequent process. For example, it may be replaced with a gate electrode (or word line) of a vertical NAND device. The sacrificial layers NL1 to NL4 may include silicon nitride, amorphous silicon, or polysilicon. In some embodiments, the sacrificial layers NL1 to NL4 may include silicon nitride.

In this embodiment, the insulating layers OL0 to OL4 may include silicon oxide, and the sacrificial layers NL1 to NL4 may include silicon nitride.

A number that the insulating layers OLD to OL4 and the sacrificial layers NL1 to NL4 alternate in the alternating stack layer 110A may be determined to correspond with the number of memory cells. For example, when 48 memory cells are vertically stacked, each of the insulating layers OLD to OL4 and the sacrificial layers NL1 to NL4 may be stacked 48 times. The insulating layers OL0 to OL4 and the sacrificial layers NL1 to NL4 may be repeatedly stacked in a direction vertical to a surface of the substrate 101.

The insulating layers OL0 to OL4 may be deposited by a chemical vapor deposition (CVD) method or an atomic layer deposition (ALD) method. The sacrificial layers NL1 to NL4 may be deposited by a chemical vapor deposition method or an atomic layer deposition method.

The lowermost layer and the uppermost layer of the alternating stack layer 110A may be the insulating layers OL0 and OL4, respectively. The insulating layers OLD to OL4 and the sacrificial layers NL1 to NL4 may have the same thickness.

As shown in FIG. 2, a sacrificial stack layer 120A may be formed on the alternating stack layer 110A. The sacrificial stack layer 120A may be of a carbon-free material. The sacrificial stack layer 120A may include first sacrificial layers HNL1 and HNL2 and second sacrificial layers HOL1 and HOL2. The first sacrificial layers HNL1 and HNL2 and the second sacrificial layers HOL1 and HOL2 may include a carbon-free insulating material. The first sacrificial layers HNL1 and HNL2 and the second sacrificial layers HOL1 and HOL2 may include at least any one insulating material selected from among silicon oxide, silicon nitride, silicon oxynitride, spin-on insulating material (SOD), insulating metal oxide, silicate, and insulating metal oxynitride. The first sacrificial layers HNL1 and HNL2 and the second sacrificial layers HOL1 and HOL2 may be deposited by a chemical vapor deposition (CVD) method or an atomic layer deposition (ALD) method.

The first sacrificial layers HNL1 and HNL2 and the second sacrificial layers HOL1 and HOL2 may be made of different materials. The first sacrificial layers HNL1 and HNL2 may include silicon nitride, and the second sacrificial layers HOL1 and HOL2 may include silicon oxide.

The first sacrificial layers HNL1 and HNL2 and the sacrificial layers NL1 to NL4 may be made of the same material. For example, the first sacrificial layers HNL1 and HNL2 and the sacrificial layers NL1 to NL4 may be made of silicon nitride. The first sacrificial layers HNL1 and HNL2 may be thinner than the sacrificial layers NL1 to NL4. In another embodiment, the first sacrificial layers HNL1 and HNL2 and the sacrificial layers NL1 to NL4 may have the same thickness. In an embodiment, the sacrificial layers NL1 to NL4 may be made of first silicon nitrides, and the first sacrificial layers HNL1 and HNL2 may be made of second silicon nitrides.

The second sacrificial layers HOL1 and HOL2 and the insulating layers OL0 to OL4 may be made of the same material. For example, the second sacrificial layers HOL1 and HOL2 and the insulating layers OL0 to OL4 may be made of silicon oxide. The second sacrificial layers HOL1 and HOL2 may be thinner than the insulating layers OL0 to OL4. In another embodiment, the second sacrificial layers HOL1 and HOL2 and the insulating layers OL0 to OL4 may have the same thickness. In an embodiment, the insulating layers OL0 to OL4 may be made of first silicon oxides, and the second sacrificial layers HOL1 and HOL2 may be made of second silicon oxides.

In the sacrificial stack layer 120A, a number that the first sacrificial layers HNL1 and HNL2 and the second sacrificial layers HOL1 and HOL2 alternate may be determined to correspond with a number that the sacrificial layers NL1 to NL4 and the insulating layers OL0 to OL4 of the alternating stack layer 110A alternate. A number that the first sacrificial layers HNL1 and HNL2 and the second sacrificial layers HOL1 and HOL2 alternate may be fewer than a number that the sacrificial layers NL1 to NL4 and the insulating layers OL0 to OL4 alternate. A thickness of the sacrificial stack layer 120A may be thinner than that of the alternating stack layer 110A. In an embodiment, the alternating stack layer 110A may include an alternating stack of first silicon oxides and first silicon nitrides, and the sacrificial stack layer 120A may include an alternating stack of second silicon oxides and second silicon nitrides.

As described above, each of the alternating stack layer 110A and the sacrificial stack layer 120A may form an oxide and nitride (oxide/nitride) (ON) stack structure in which oxides and nitrides are alternately stacked. Accordingly, the ON stack structure may be an etch target layer, and a lower level of the ON stack structure may correspond to the alternating stack layer 110A, and a higher level of the ON stack structure may correspond to the sacrificial stack layer 120A. In embodiments, the sacrificial stack layer 120A may be formed on an upper level of the ON stack structure where bowing is to be generated, and the sacrificial stack layer 120A on which bowing is generated after a subsequent etching process may be removed.

Subsequently, an etching process of the etch target layer including the alternating stack layer 110A and the sacrificial stack layer 120A may be performed.

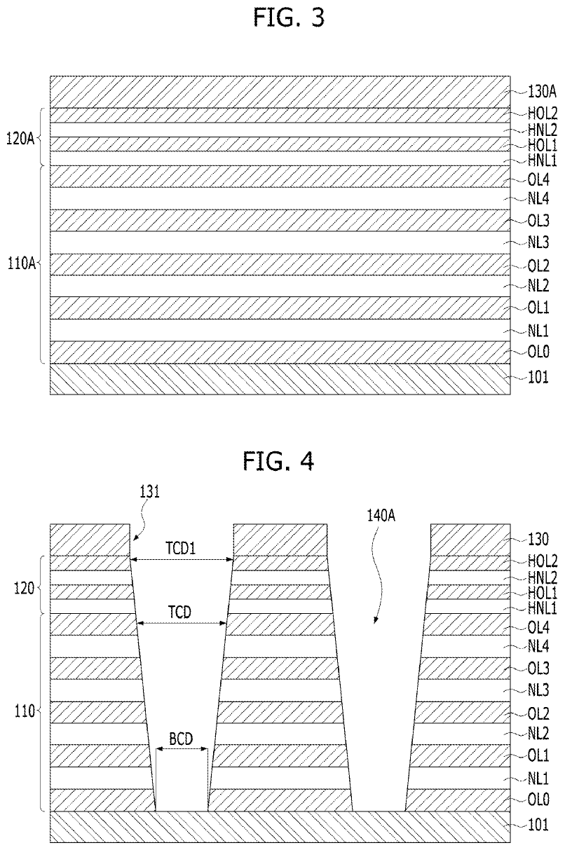

As shown in FIG. 3, a hard mask layer 130A may be formed on the uppermost second sacrificial layer HOL2. The hard mask layer 130A may include at least a carbon-containing material. The hard mask layer 130A may include amorphous carbon. A thickness of the hard mask layer 130A may be thinner than that of the sacrificial stack layer 120A. In another embodiment, the hard mask layer 130A and the sacrificial stack layer 120A may have the same thickness.

As shown in FIG. 4, a hard mask pattern 130 may be formed. The hard mask pattern 130 may be formed by dry etching the hard mask layer 130A using a photoresist pattern (not shown). The hard mask pattern 130 may include an opening 131. A width of the opening 131 may be defined to be larger than an upper width TCD of high aspect ratio features 140 to be described below.

Subsequently, a plurality of initial high aspect ratio features 140A may be formed by etching processes of the sacrificial stack layer 120A and the alternating stack layer 110A, the etching processes using the hard mask pattern 130. A sacrificial stack 120 may be formed by an etching process of the sacrificial stack layer 120A, and an alternating stack 110 may be formed by an etching process of the alternate stack layer 110A. The initial high aspect ratio features 140A may penetrate the sacrificial stack 120 and the alternating stack 110. The initial high aspect ratio features 140A may extend vertically to the substrate 101. The initial high aspect ratio features 140A may include a top width TCD1, the upper width TCD, and a bottom width BCD, whose widths decrease from the sacrificial stack 120 toward the substrate 101, that is, along a depth direction. The initial high aspect ratio features 140A may have a sloped sidewall. For example, the bottom width BCD of the initial high aspect ratio features 140A may be narrower than the upper width TCD, and the upper width TCD may be narrower than the top width TCD1. In an embodiment, the bottom width BCD of the initial high aspect ratio features 140A is defined by etching of the insulating layers OL0, the upper width TCD of the initial high aspect ratio features 140A is defined by etching of the insulating layers OL4, and the top width TCD1 of the initial high aspect ratio features 140A is defined by etching of the uppermost second sacrificial layer HOL2.

A method for forming the initial high aspect ratio features 140A will be described below.

The sacrificial stack layer 120A and the alternating stack layer 110A may be sequentially dry etched using the hard mask pattern 130 as an etch barrier. In an embodiment, the sacrificial stack layer 120A may be dry etched using the hard mask pattern 130 as an etch barrier, and the alternating stack layer 110A may be dry etched using the hard mask pattern 130 and the sacrificial stack 120 as an etch barrier. Accordingly, the sacrificial stack 120 and the alternating stack 110 may be formed, and the sacrificial stack 120 may define an uppermost level of the initial high aspect ratio features 140A. The uppermost level of the initial high aspect ratio features 140A defined by the sacrificial stack 120 may have a wide top width TCD1 and a sloped sidewall. The top width TCD1 of the initial high aspect ratio features 140A may be wider than the upper width TCD of the initial high aspect ratio features 140A. The uppermost level of the initial high aspect ratio features 140A may include a bowing profile.

The initial high aspect ratio features 140A may expose the substrate 101 by dry etching the alternating stack layer 110A.

As described above, by defining the top width TCD1 of the sacrificial stack 120 to be large, where the bowing has occurred, an open margin of the initial high aspect ratio features 140A increases, thereby the bottom width BCD may be secured to be sufficiently large.

As a result, even if a height of the initial high aspect ratio features 140A increases, the bottom width BCD may be secured to be sufficiently large.

In comparison, when the sacrificial stack 120 is omitted, the upper width TCD of the initial high aspect ratio features 140A may be a bow width where the bowing is generated, and it may be difficult to secure the bottom width BCD of the initial high aspect ratio features 140A to be sufficiently large.

When viewed from a top view, the initial high aspect ratio features 140A may be a circle shape, a linear shape, a square shape, a triangular shape, or an ellipse shape. In some embodiments, the plurality of initial high aspect ratio features 140A may form a hole array arranged with uniform spacing. The hard mask pattern 130 may be referred to as a carbon-containing hard mask, and the sacrificial stack 120 may be referred to as a carbon-free hard mask. In an embodiment, the alternating stack layer 120A may include an alternating stack of first silicon oxides and first silicon nitrides, the carbon-free hard mask may include an alternating stack of second silicon oxides and second silicon nitrides, and the carbon-containing hard mask may include amorphous carbon layer.

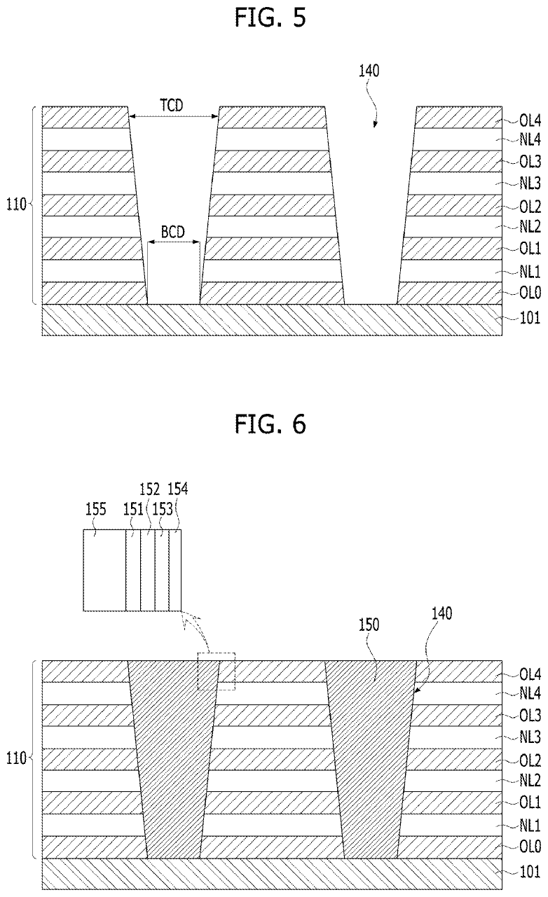

As shown in FIG. 5, the hard mask pattern 130 and the sacrificial stack 120 may be removed. By removing the sacrificial stack 120, a portion where the bowing has occurred may be removed. The sacrificial stack 120 may be removed by an etchback process. As the sacrificial stack 120 is removed, a high aspect ratio features 140 may be formed. The high aspect ratio features 140 may have a lower height than the initial high aspect ratio features 140A. The high aspect ratio features 140 may include an upper width (TCD) and a bottom width (BCD). The bottom width BCD of the high aspect ratio features 140 may be smaller than the upper width TCD of the high aspect ratio features 140. The high aspect ratio features 140 may have a sloped sidewall.

As shown in FIG. 6, a plurality of vertical channel structures 150 penetrating through the alternating stack 110 may be formed. The vertical channel structures 150 may fill the high aspect ratio features 140. The vertical channel structures 150 may extend vertically to a surface of the substrate 101. The vertical channel structures 150 may penetrate through the insulating layers OL0 to OL4 and the sacrificial layers NL1 to NL4. The vertical channel structures 150 may extend vertically to a stacking direction of the insulating layers OL0 to OL4 and the sacrificial layers NL1 to NL4.

For example, each of the vertical channel structures 150 may include a channel layer 151, a tunnel insulating layer 152, a charge trap layer 153, and a blocking layer 154. A core insulating layer 155 may be formed inside the channel layer 151. The blocking layer 154 may be formed on each of the high aspect ratio features 140. The blocking layer 154 may include silicon oxide, a high-k material, or a combination thereof. For example, the blocking layer 154 may include silicon oxide, aluminum oxide, hafnium oxide, zirconium oxide, or a combination thereof. The charge trap layer 153 may include a charge trap insulating material such as silicon nitride. The charge trap layer 153 may be conformally formed on the blocking layer 214. The tunnel insulating layer 152 may be formed on the charge trap layer 153. The tunnel insulating layer 152 may include silicon oxide. The channel layer 151 may be formed on the tunnel insulating layer 152. The channel layer 151 may include a semiconductor material. For example, the channel layer 151 may include any one of a polycrystalline semiconductor material, an amorphous semiconductor material, or a monocrystalline semiconductor material. The channel layer 151 may include silicon (Si), germanium (Ge), silicon germanium (SiGe), a group III-V compound, or a group II-VI compound. The channel layer 151 may include polysilicon. At least one or more other layers including the core insulating layer 155 may further be formed on the channel layer 151.

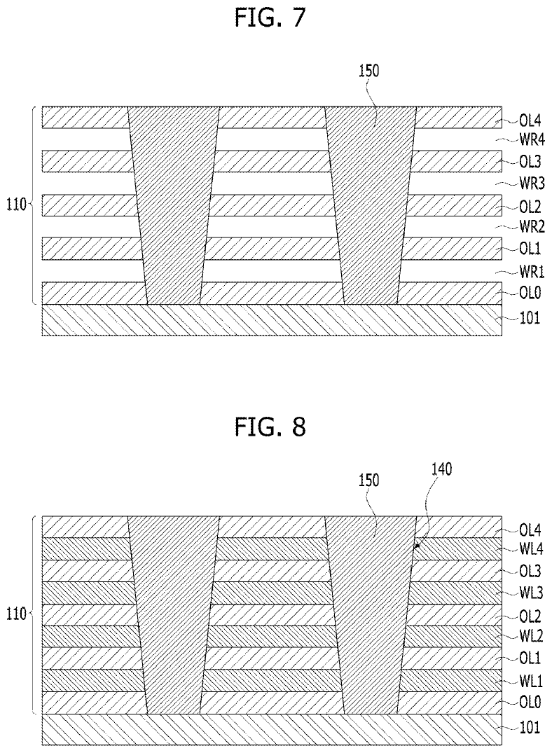

Subsequently, a process of replacing the sacrificial layers NL1 to NL4 with gate electrodes WL1 to WL4 may be performed as illustrated in FIGS. 7 and 8.

As shown in FIG. 7, the sacrificial layers NL1 to NL4 of the alternating stack 110 may be selectively removed. Accordingly, lateral recesses WR1 to WR4 may be formed between the insulating layers OL0 to OL4. The lateral recesses WR1 to WR4 may be referred to as a lateral air gap. In an embodiment, the lateral recesses WR1 to WR4 may be referred to as a lateral gap. In an embodiment, the lateral gap may include a gas, for example, but not limited to air. Lateral recesses WR1 to WR4 and insulating layers OL1 to OL4 may be alternately stacked on the substrate 101. When the sacrificial layers NL1 to NL4 include silicon nitride, the sacrificial layers NL1 to NL4 may be removed by a chemical containing phosphoric acid (H₃PO₄).

Although not shown, a slit penetrating the alternating stack 110 may be formed, and the sacrificial layers NL1 to NL4 may be removed by providing a chemical through the slit. The slit is a line-shaped feature having a high aspect ratio, and an etching process for forming the slit may also use the sacrificial stack as an etching barrier as described above. For example, a process of forming an additional sacrificial stack layer on an upper portion of the alternating stack 110 of FIG. 6, an etching process of an additional sacrificial stack layer to form the additional sacrificial stack, and an etching process of the alternating stack 110 using the additional sacrificial stack as a hard mask may be performed.

As shown in FIG. 8, the gate electrodes WL1 to WL4 may be formed. The gate electrodes WL1 to WL4 may fill the lateral recesses WR1 to WR4, respectively. The insulating layers OL0 to OL4 and the gate electrodes WL1 to WL4 may be alternately stacked on the substrate 101.

The gate electrodes WL1 to WL4 may include a low resistance material. The gate electrodes WL1 to WL4 may be a metal-based material. The gate electrodes WL1 to WL4 may include metal, metal silicide, metal nitride, or a combination thereof. For example, the metal may include nickel, cobalt, platinum, titanium, tantalum, or tungsten. The metal silicide may include nickel silicide, cobalt silicide, platinum silicide, titanium silicide, tantalum silicide, or tungsten silicide. The gate electrodes WL1 to WL4 may include a stack of titanium nitride and tungsten.

According to the above-described embodiment, the upper width TCD of the high aspect ratio features 140 may be increased by using an uppermost portion of the ON stack, that is, the sacrificial stack 120, in which oxides and nitrides alternate, as a hard mask. By removing the sacrificial stack 120, the bottom width BCD of the high aspect ratio features 140 may be secured without an increase in the bow width.

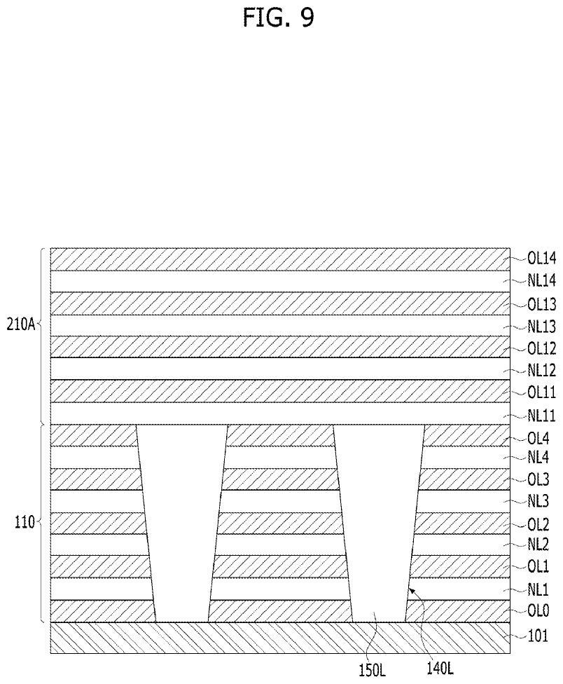

FIGS. 9 to 15 illustrate a method for fabricating a semiconductor device according to an embodiment. In FIGS. 9 to 15, the same reference numerals as in FIGS. 1 to 8 denote the same elements, and detailed descriptions thereof will be omitted below.

First, referring to FIGS. 1 to 5, the high aspect ratio features 140 penetrating through the alternating stack 110 of the insulating layers OL0 to OL4 and the sacrificial layers NL1 to NL4 may be formed on the substrate 101.

As shown in FIG. 9, an alternating stack of the insulating layers OL0 to OL4 and the sacrificial layers NL1 to NL4 is abbreviated as a ‘lower-level alternating stack 110’. The high aspect ratio features 140 of the insulating layers OL0 to OL4 and the sacrificial layers NL1 to NL4 are abbreviated as ‘lower-level high aspect ratio features 140L’.

Next, the high aspect ratio features 140L may be filled with a sacrificial pillar 150L. The sacrificial pillar 150L may include oxide or nitride. In another embodiment, the sacrificial pillar 150L may be of a material different from the alternating stack 110.

Next, an upper-level alternating stack layer 210A may be formed by stacking a plurality of layers formed of different materials on the sacrificial pillar 150L and the lower-level alternating stack 110. The upper-level alternating stack layer 210A is a stacked body and may be similar to the lower-level alternating stack 110. For example, in the upper-level alternating stack layer 210A, sacrificial layers NL11 to NL14 and insulating layers OL11 to OL14 may be alternately stacked. The insulating layers OL11 to OL14 may include an insulating material, and the sacrificial layers NL11 to NL14 may include a sacrificial material. The insulating layers OL11 to OL14 may include at least any one insulating material selected from among silicon oxide, silicon nitride, silicon oxynitride, spin-on insulating material (SOD), insulating metal oxide, silicate, and insulating metal oxynitride. The uppermost layer of the upper-level alternating stack layer 210A may be the insulating layer OL14.

The sacrificial layers NL11 to NL14 may include a sacrificial material that may be selectively removed from the insulating layers OL11 to OL14. The sacrificial layers NL11 to NL14 may include an insulating material. The sacrificial layers NL11 to NL14 may be replaced with a conductive material in a subsequent process. For example, it may be replaced with a gate electrode (or word line) of a vertical NAND device. The sacrificial layers NL11 to NL14 may include silicon nitride, amorphous silicon, or polysilicon. In some embodiments, the sacrificial layers NL11 to NL14 may include silicon nitride.

In this embodiment, the insulating layers OL11 to OL14 may include silicon oxide, and the sacrificial layers NL11 to NL14 may include silicon nitride.

In the upper-level alternating stack layer 210A, a number that the insulating layers OL11 to OL14 and the sacrificial layers NL11 to NL14 alternate may be determined to correspond with the number of memory cells.

The insulating layers OL11 to OL14 may be deposited by a chemical vapor deposition (CVD) method or an atomic layer deposition (ALD) method. The sacrificial layers NL11 to NL14 may be deposited by a chemical vapor deposition method or an atomic layer deposition method.

The insulating layers OL0 to OL4 of the lower-level alternating stack 110 and the insulating layers OL11 to OL14 of the upper-level alternating stack layer 210A may be made of the same material. The sacrificial layers NL1 to NL4 of the lower-level alternating stack 110 and the sacrificial layers NL11 to NL14 of the upper-level alternating stack layer 210A may be formed of the same material.

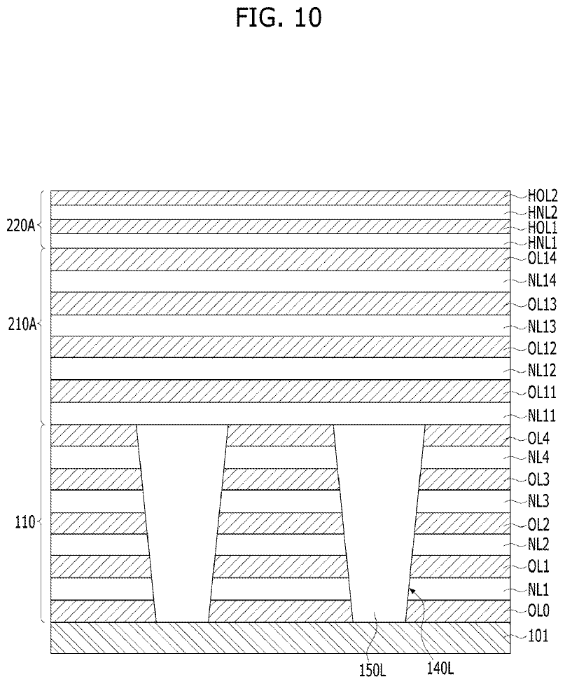

As shown in FIG. 10, a sacrificial stack layer 220A may be formed on the upper-level alternating stack layer 210A. The sacrificial stack layer 220A may be a carbon-free material. The sacrificial stack layer 220A may include the first sacrificial layers HNL1 and HNL2 and the second sacrificial layers HOL1 and HOL2. The first sacrificial layers HNL1 and HNL2 and the second sacrificial layers HOL1 and HOL2 may include a carbon-free insulating material. The first sacrificial layers HNL1 and HNL2 and the second sacrificial layers HOL1 and HOL2 may include at least any one insulating material selected from among silicon oxide, silicon nitride, silicon oxynitride, spin-on insulating material (SOD), insulating metal oxide, silicate, and insulating metal oxynitride.

The first sacrificial layers HNL1 and HNL2 and the second sacrificial layers HOL1 and HOL2 may be made of different materials. The first sacrificial layers HNL1 and HNL2 may include silicon nitride, and the second sacrificial layers HOL1 and HOL2 may include silicon oxide.

The first sacrificial layers HNL1 and HNL2 and the sacrificial layers NL1 to NL4 and NL11 to NL14 may be made of the same material, for example, the first sacrificial layers HNL1 and HNL2 and the sacrificial layers NL1 to NL4 and NL11 to NL14 may be silicon nitride.

The second sacrificial layers HOL1 and HOL2 and the insulating layers OL0 to OL4 and OL11 to OL14 may be made of the same material. For example, the second sacrificial layers HOL1 and HOL2 and the insulating layers OL0 to OL4 and OL11 to OL14 may be silicon oxide.

In the sacrificial stack layer 220A, the number of alternations between the first sacrificial layers HNL1 and HNL2 and the second sacrificial layers HOL1 and HOL2 may correspond to the number of alternations between the insulating layers OL11 to OL14 and the sacrificial layers NL11 to NL14 of the upper-level alternating stack layer 210A.

The first sacrificial layers HNL1 and HNL2 and the second sacrificial layers HOL1 and HOL2 may be deposited by a chemical vapor deposition (CVD) method or an atomic layer deposition (ALD) method.

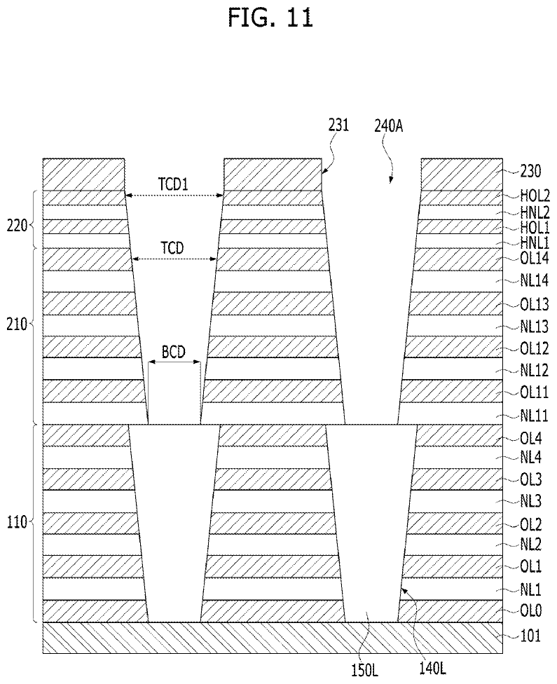

As shown in FIG. 11, a hard mask pattern 230 may be formed on the second sacrificial layer HOL2, which is the uppermost layer among the second sacrificial layers HOL1 and HOL2. The hard mask pattern 230 may be formed by dry etching an amorphous carbon layer (not shown) using a photoresist pattern (not shown). The hard mask pattern 230 may include an opening 231. A width of the opening 231 may be defined to be larger than the upper width TCD of initial upper-level high aspect ratio features 240A to be described below.

Subsequently, the initial upper-level high aspect ratio features 240A may be formed by etching processes of the sacrificial stack layer 220A and the upper-level alternating stack layer 210A using the hard mask pattern 230. The sacrificial stack 220 may be formed by an etching process of the sacrificial stack layer 220A, and an upper-level alternating stack 210 may be formed by an etching process of the upper-level alternating stack layer 210A. The initial upper-level high aspect ratio features 240A may penetrate through the sacrificial stack 220 and the upper-level alternating stack 210. The initial upper-level high aspect ratio features 240A may extend vertically to the sacrificial pillar 150L. The initial upper-level high aspect ratio features 240A may have the same shape as the lower-level high aspect ratio features 140L. Each of the initial upper-level high aspect ratio features 240A may include the top width TCD1, the upper width TCD, and the bottom width BCD, whose widths decrease from the sacrificial stack 220 toward the sacrificial pillar 150L, that is, along a depth direction. The initial upper-level high aspect ratio features 240A may have a sloped sidewall. For example, the bottom width BCD of the initial upper-level high aspect ratio features 240A may be narrower than the upper width TCD of the initial upper-level high aspect ratio features 240A, and the upper width TCD of the initial upper-level high aspect ratio features 240A may be narrower than the top width TCD1 of the initial upper-level high aspect ratio features 240A. In an embodiment, the bottom width BCD of the initial upper-level high aspect ratio features 240A is defined by etching of the sacrificial layers NL11, the upper width TCD of the initial upper-level high aspect ratio features 240A is defined by etching of the insulating layers OL14, and the top width TCD1 of the initial upper-level high aspect ratio features 240A is defined by etching of the uppermost second sacrificial layer HOL2.

A method for forming the initial high-level high aspect ratio features 240A will be described below.

The sacrificial stack layer 220A and the upper-level alternating stack layer 210A may be sequentially dry etched using the hard mask pattern 230 as an etch barrier. In an embodiment, the sacrificial stack layer 220A may be dry etched using the hard mask pattern 230 as an etch barrier, and the alternating stack layer 210A may be dry etched using the hard mask pattern 230 and the sacrificial stack 220 as an etch barrier. Accordingly, the sacrificial stack 220 and the upper-level alternating stack 210 may be formed, and the sacrificial stack 220 may define an uppermost level of the initial upper-level high aspect ratio features 240A. The uppermost level of the initial upper-level high aspect ratio features 240A defined by the sacrificial stack 220 may have a wide top width TCD1 and a sloped sidewall. The top width TCD1 of the initial upper-level high aspect ratio features 240A may be wider than the upper width TCD of the initial upper-level high aspect ratio features 240A. The uppermost level of the initial upper-level high aspect ratio features 240A may include a bowing profile.

Each of the initial upper-level high aspect ratio features 240A may expose the sacrificial pillar 150L by dry etching the upper-level alternating stack 210.

As described above, by defining the top width TCD1 of the sacrificial stack 220 to be large, an open margin of the initial upper-level high aspect ratio features 240A increases, thereby the bottom width BCD may be secured to be sufficiently large.

As a result, even if a height of the initial upper-level high aspect ratio features 240A increases, the bottom width BCD may be secured to be sufficiently large.

Dry etching of the sacrificial stack layer 220A and the upper-level alternating stack layer 210A may be performed using the same etching gas.

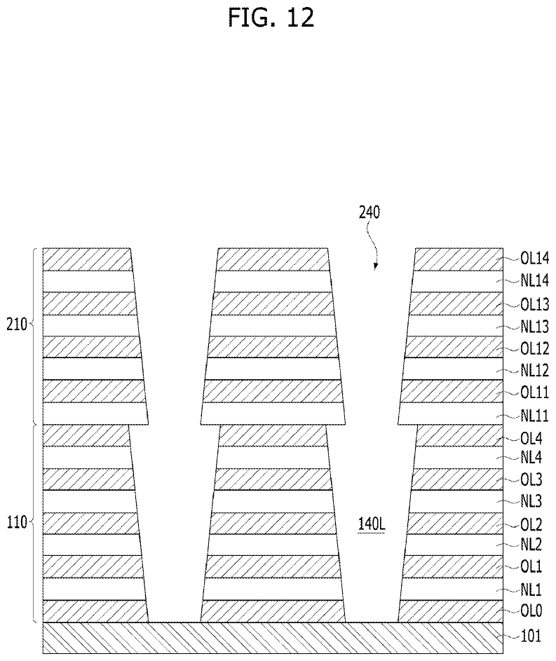

As shown in FIG. 12, the hard mask pattern 230 and the sacrificial stack 220 may be removed. The sacrificial stack 220 may be removed by an etchback process. As the sacrificial stack 220 is removed, an upper-level high aspect ratio features 240 may be formed. The upper-level high aspect ratio features 240 may have a lower height than the initial upper-level high aspect ratio features 240A. The upper-level high aspect ratio features 240 may include an upper width (TCD) and a bottom width (BCD). The bottom width BCD of the upper-level high aspect ratio features 240 may be smaller than the upper width TCD of the upper-level high aspect ratio features 240. The upper-level high aspect ratio features 240 may have a sloped sidewall.

Next, the sacrificial pillar 150L may be removed, and accordingly, the lower-level high aspect ratio features 140L may be exposed again.

The lower-level high aspect ratio features 140L and the upper-level high aspect ratio features 240 may be vertically connected.

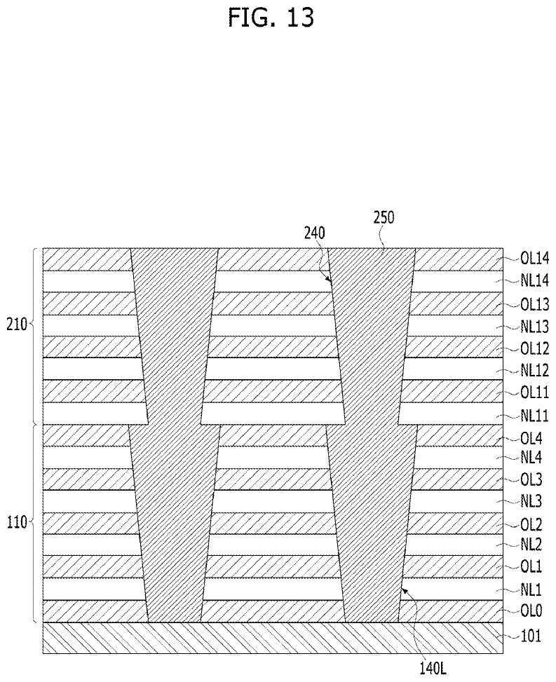

As shown in FIG. 13, a plurality of vertical channel structures 250 penetrating the upper-level alternating stack 210 and the lower-level alternating stack 110 may be formed. The vertical channel structures 250 may fill the lower-level high aspect ratio features 140L and the upper-level high aspect ratio features 240. The vertical channel structures 250 may extend in a vertical direction from a surface of the substrate 101. The vertical channel structures 250 may penetrate through the insulating layers OL11 to OL14 and OL0 to OL4 and the sacrificial layers NL11 to NL14 and NL1 to NL4, and may extend vertically along a stacking direction of the insulating layers OL11 to OL14 and OL0 to OL4 and the sacrificial layers NL11 to NL14 and NL1 to NL4.

The vertical channel structures 250 may have the same structure as the vertical channel structures 150 of FIG. 6. For example, as shown in FIG. 6, each of the vertical channel structures 250 may include the vertical channel layer 151, the tunnel insulating layer 152, the charge trap layer 153, and the blocking layer 154.

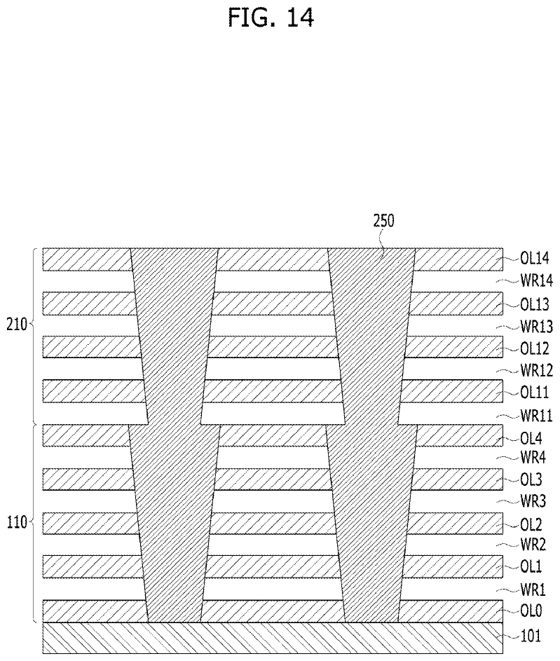

As illustrated in FIG. 14, the sacrificial layers NL1 to NL4 and NL11 to NL14 of the lower-level alternating stack 110 and the upper-level alternating stack 210 may be selectively removed. Accordingly, the lateral recesses WR1 to WR4 and lateral recesses WR11 to WR14 may be formed between the insulating layers OL0 to OL4 and OL11 to OL14. The lateral recesses WR1 to WR4 and WR11 to WR14 may be referred to as a lateral air gap. In an embodiment, the lateral recesses WR1 to WR4 may be referred to as a lateral gap. In an embodiment, the lateral gap may include a gas, for example, but not limited to air. The lateral recesses WR1 to WR4 and WR11 to WR14 and the insulating layers OL1 to OL4 and OL11 to OL14 may be alternately stacked. When the sacrificial layers NL1 to NL4 and NL11 to NL14 include silicon nitride, the sacrificial layers NL1 to NL4 and NL11 to NL14 may be removed by a chemical containing phosphoric acid (H₃PO₄).

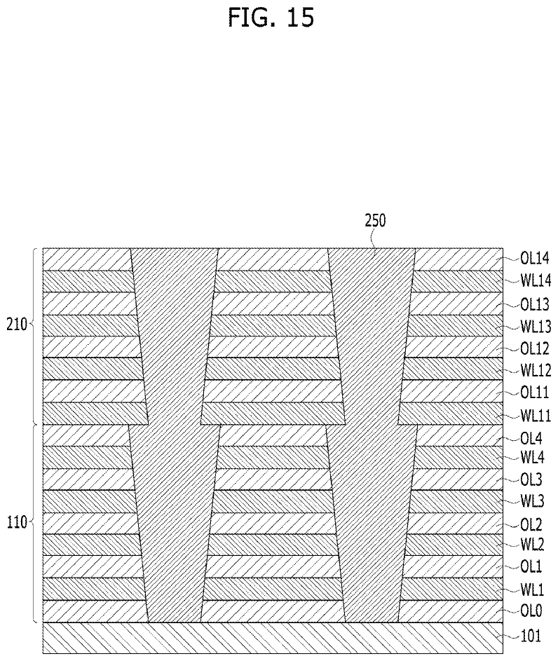

As shown in FIG. 15, the gate electrodes WL1 to WL4 and gate electrodes WL11 to WL14 may be formed. The gate electrodes WL1 to WL4 and WL11 to WL14 may fill the lateral recesses WR1 to WR4 and WR11 to WR14, respectively. The insulating layers OL0 to OL4 and OL11 to OL14 and the gate electrodes WL1 to WL4 and WL11 to WL14 may be alternately stacked.

The gate electrodes WL1 to WL4 and WL11 to WL14 may include a low resistance material. The gate electrodes WL1 to WL4 and WL11 to WL14 may be a metal-based material. The gate electrodes WL1 to WL4 and WL11 to WL14 may include metal, metal silicide, metal nitride, or a combination thereof. For example, the metal may include nickel, cobalt, platinum, titanium, tantalum, or tungsten. The metal silicide may include nickel silicide, cobalt silicide, platinum silicide, titanium silicide, tantalum silicide, or tungsten silicide. The gate electrodes WL1 to WL4 and WL11 to WL14 may include a stack of titanium nitride and tungsten.

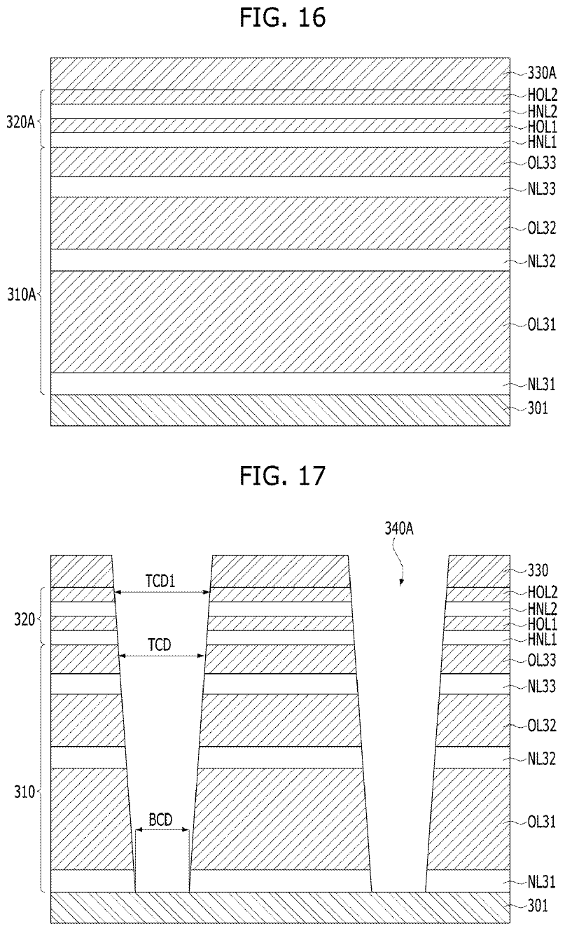

FIGS. 16 to 22 illustrate a method for fabricating a semiconductor device according to an embodiment. In FIGS. 16 to 22, the same reference numerals as in FIGS. 1 to 15 denote the same elements, and detailed descriptions thereof will be omitted below.

As shown in FIG. 16, an alternating stack layer 310A may be formed by stacking a plurality of layers formed of different materials on a lower structure 301 including a conductive structure (not shown). The conductive structure may include polysilicon, metal, metal nitride, metal silicide, or a combination thereof. The lower structure 301 may include a semiconductor substrate (not shown) and an interlayer insulating layer (not shown), and the conductive structure may be connected to the semiconductor substrate by penetrating through the interlayer insulating layer.

The alternating stack layer 310A may include a plurality of first layers NL31 to NL33 and a plurality of second layers OL31 to OL33. The first layers NL31 to NL33 and the second layers OL31 to OL33 may be alternately stacked. The first layers NL31 to NL33 and the second layers OL31 to OL33 may be made of different materials. The first layers NL31 to NL33 and the second layers OL31 to OL33 may be formed using a deposition process such as chemical vapor deposition (CVD), atomic layer deposition (ALD), or physical vapor deposition (PVD). The second layers OL31 to OL33 may include silicon oxide doped with phosphorus or silicon oxide doped with boron. The second layers OL31 to OL33 may include undoped silicate glass (USG), phospho silicate glass (PSG), boro silicate glass (BSG), boro phospho silicate glass (BPSG), fluoride silicate glass (FSG), or a combination thereof. The first layers NL31 to NL33 may be formed of a material having an etch selectivity with respect to the second layers OL31 to OL33. The first layers NL31 to NL33 may include silicon nitride (Si₃N₄) or silicon carbon nitride (SiCN). The second layers OL31 to OL33 may be thicker than the first layers NL31 to NL33.

A sacrificial stack layer 320A may be formed on the alternating stack layer 310A. The sacrificial stack layer 320A may be made of a material that does not contain carbon. The sacrificial stack layer 320A may include the first sacrificial layers HNL1 and HNL2 and the second sacrificial layers HOL1 and HOL2. The first sacrificial layers HNL1 and HNL2 and the second sacrificial layers HOL1 and HOL2 may include an insulating material containing no carbon. The first sacrificial layers HNL1 and HNL2 and the second sacrificial layers HOL1 and HOL2 may include at least any one insulating material selected from among silicon oxide, silicon nitride, silicon oxynitride, a spin-on insulating material (SOD), insulating metal oxide, silicate, and insulating metal oxide.

The first sacrificial layers HNL1 and HNL2 and the second sacrificial layers HOL1 and HOL2 may be of different materials. The first sacrificial layers HNL1 and HNL2 may include silicon nitride, and the second sacrificial layers HOL1 and HOL2 may include silicon oxide.

The first sacrificial layers HNL1 and HNL2 and the first layers NL31 to NL33 may be made of the same material, and for example, the first sacrificial layers HNL1 and HNL2 and the first layers NL31 to NL33 may be made of silicon nitride. The second sacrificial layers HOL1 and HOL2 and the second layers OL31 to OL33 may be the same material. For example, the second sacrificial layers HOL1 and HOL2 and the second layers OL31 to OL33 may be made of silicon oxide.

In the sacrificial stack layer 320A, a number that the first sacrificial layers HNL1 and HNL2 and the second sacrificial layers HOL1 and HOL2 alternate may be determined to correspond with a number that the first layers NL31 to NL33 and the second layers OL31 to OL33 alternate.

The first sacrificial layers HNL1 and HNL2 and the second sacrificial layers HOL1 and HOL2 may be deposited by a chemical vapor deposition (CVD) method or an atomic layer deposition (ALD) method.

A hard mask layer 330A may be formed on the second sacrificial layer HOL2, which is the uppermost layer among the second sacrificial layers HOL1 and HOL2. The hard mask layer 330A may include a carbon-containing material. The hard mask layer 330A may include amorphous carbon layer.

As described above, a stack structure of the sacrificial stack layer 320A and the hard mask layer 330A may be formed on the alternating stack layer 310A. The sacrificial stack layer 320A may include an ON stack of oxides and nitrides, and the hard mask layer 330A may include amorphous carbon.

As shown in FIG. 17, a hard mask pattern 330 may be formed. The hard mask pattern 330 may be formed by etching the hard mask layer 330A using a photoresist pattern (not shown). The hard mask pattern 330 may include amorphous carbon layer pattern.

Subsequently, initial high aspect ratio features 340A may be formed by a series of etching processes using the hard mask pattern 330. The initial high aspect ratio features 340A may penetrate through the sacrificial stack layer 320A and the alternating stack layer 310A. The initial high aspect ratio features 340A may extend vertically to the lower structure 301. The initial high aspect ratio features 340A may have a sloped sidewall.

To form the initial high aspect ratio features 340A, the sacrificial stack layer 320A and the alternating stack layer 310A may be sequentially dry etched using the hard mask pattern 330 as an etch barrier. The initial high aspect ratio features 340A may be referred to as a hole in which a lower electrode (or storage node) is to be formed. The initial high aspect ratio features 340A may have high aspect ratio. The initial high aspect ratio features 340A may have a height to width ratio of 1:10 or more. In an embodiment, the bottom width BCD of the initial high aspect ratio features 340A is defined by etching of the first layer NL31, the upper width TCD of the initial high aspect ratio features 340A is defined by etching of the second layer OL33, and the top width TCD1 of the initial high aspect ratio features 340A is defined by etching of the uppermost second sacrificial layer HOL2.

A method for forming the initial high aspect ratio features 340A is as follows.

First, the sacrificial stack layer 320A and the alternating stack layer 310A may be sequentially dry etched using the hard mask pattern 330 as an etch barrier. In an embodiment, the sacrificial stack layer 320A may be dry etched using the hard mask pattern 330 as an etch barrier, and the alternating stack layer 310A may be dry etched using the hard mask pattern 330 and the sacrificial stack 120 as an etch barrier. Accordingly, the sacrificial stack 320 and the alternating stack 310 may be formed, and the sacrificial stack 320 may define an uppermost level of the initial high aspect ratio features 340A. The uppermost level of the initial high aspect ratio features 340A defined by the sacrificial stack 320 may have a wide top width TCD1 and a sloped sidewall. The top width TCD1 of the initial high aspect ratio features 340A may be wider than the upper width TCD of the initial high aspect ratio features 340A. The uppermost level of the initial high aspect ratio features 340A may include a bowing profile.

When the second layer OL31 of the alternating stack layer 310A is etched, the first layer NL31, the lowermost layer among the first layers NL31 to NL33, may serve as an etch stop layer, and the first layer NL31 may be etched to expose the lower structure 301 through successive etching.

In another embodiment, the initial high aspect ratio features 340A may be formed by a double patterning process. For example, the hard mask pattern 330 for forming the initial high aspect ratio features 340A may be a mesh-shape formed by combining two spacer patterning techniques.

As described above, by defining the top width TCD1 of the sacrificial stack 320 to be large, an open margin of the initial high aspect ratio features 340A increases, thereby the bottom width BCD may be secured to be sufficiently large.

As a result, even if a height of the initial high aspect ratio features 340A increases, the bottom width BCD may be secured to be sufficiently large.

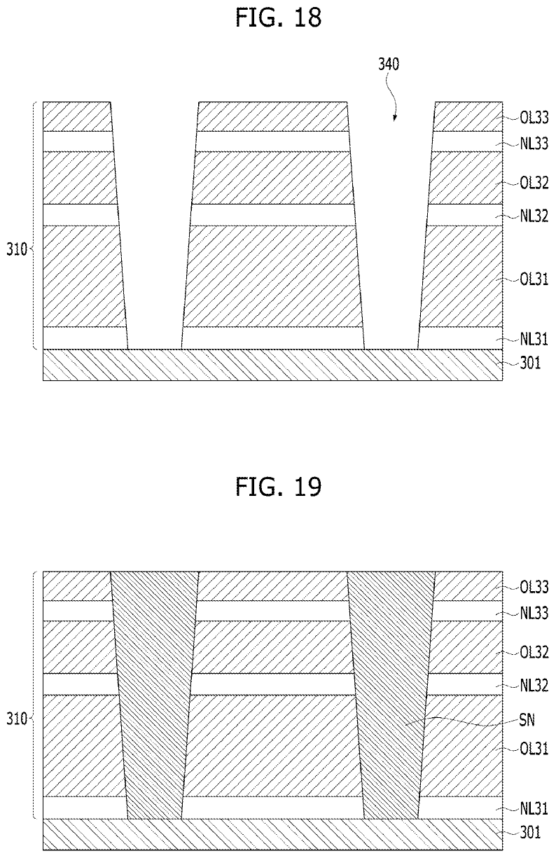

As shown in FIG. 18, the hard mask pattern 330 and the sacrificial stack 320 may be removed. The sacrificial stack 320 may be removed by an etchback process. As the sacrificial stack 320 is removed, a high aspect ratio features 340 may be formed. The high aspect ratio features 340 may have a lower height than the initial high aspect ratio features 340A. The high aspect ratio features 340 may include an upper width (TCD) and a bottom width (BCD). The bottom width BCD of the high aspect ratio features 340 may be smaller than the upper width TCD of the high aspect ratio features 340. The high aspect ratio features 340 may have a sloped sidewall.

As illustrated in FIG. 19, each of storage nodes SN may be formed in each of the high aspect ratio features 340. Each of the storage nodes SN may fill an interior of the high aspect ratio features 340. The storage nodes SN may have a pillar-shape. In order to form storage nodes SN of a pillar-shape, planarization may be performed after depositing a conductive material to gap-fill the high aspect ratio features 340. The storage nodes SN may include at least one selected from among polysilicon, metal, metal nitride, conductive metal oxide, metal silicide, noble metal, or a combination thereof. The storage nodes SN may include at least any one from among titanium (Ti), titanium nitride (TIN), tantalum (Ta), tantalum nitride (TaN), titanium aluminum nitride (TiAlN), tungsten (W) or tungsten nitride (WN), ruthenium (Ru), ruthenium oxide (RuO₂), iridium (Ir), iridium oxide (IrO₂), platinum (Pt), or a combination thereof. The storage nodes SN may include titanium nitride (TiN). The storage nodes SN may include titanium nitride (ALD-TiN) formed through atomic layer deposition (ALD). In another embodiment, the storage nodes SN may include a stack of cylindrical titanium nitride and pillar-type polysilicon filled in the cylindrical titanium nitride.

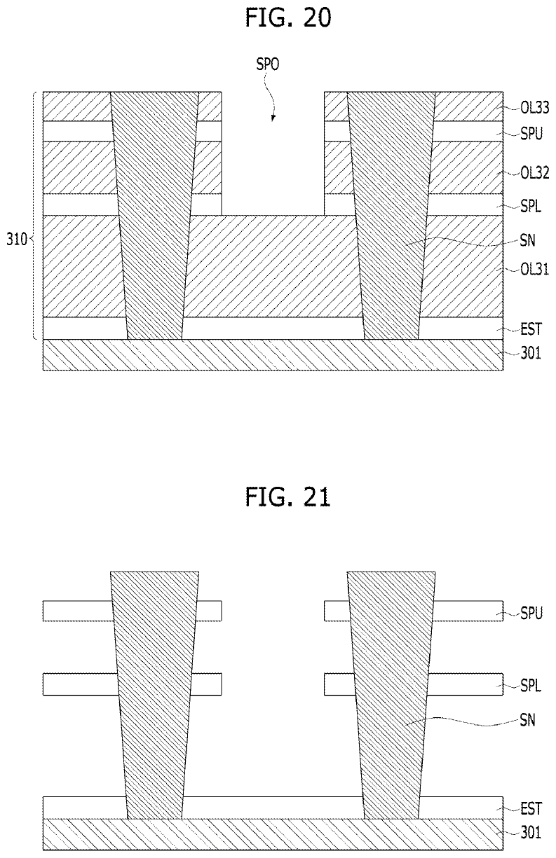

As shown in FIG. 20, a supporter opening SPO may be formed. In order to form the supporter opening SPO, a portion of the alternating stack 310 may be etched. For example, the first layers NL32 and NL33 and the second layers OL32 and OL33 may be etched. After the supporter opening SPO is formed, the first layers NL32 and NL33 may become a plate-shaped supporter. For example, the first layer NL32 may be patterned with a lower-level supporter SPL, and the first layer NL33 may be patterned with an upper-level supporter SPU. Each of the lower-level supporter SPL and the upper-level supporter SPU may support the storage nodes SN. Some surfaces of the second layer OL31 may be exposed by the lower-level supporter SPL. The lower-level and upper-level supporters SPL and SPU may prevent or mitigate the storage nodes SN from being collapsed during a subsequent deep out process. The first layer NL31 may be abbreviated as an etch stop layer EST. The lower-level supporter SPL and the upper-level supporter SPU may be referred to as a multi-level supporter.

When viewed from a top view, the supporter opening SPO may have a shape that partially exposes upper outer walls of three neighboring storage nodes SN. In another embodiment, the supporter opening SPO may have a shape that partially exposes upper outer walls of at least four storage nodes SN. A cross-sectional shape of the supporter opening SPO may have a triangular, square, parallelogram, pentagonal, hexagonal, or honeycomb shape.

As shown in FIG. 21, the second layers OL31 to OL33 may be removed by a wet dip-out process. The wet dip-out process for removing the second layers OL31 to OL33 may be performed using an etching solution capable of selectively removing the second layers OL31 to OL33. When the second layers OL31 to OL33 include silicon oxide, wet etching using hydrofluoric acid (HF) may be performed.

Each of the storage nodes SN may be supported by the lower-level supporter SPL and the upper-level supporter SPU.

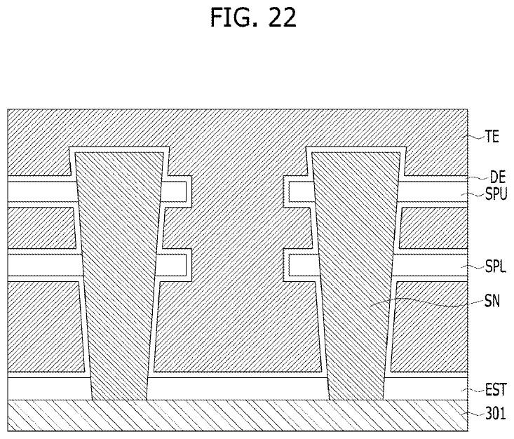

As shown in FIG. 22, a dielectric layer DE may be formed on the storage nodes SN. The dielectric layer DE may include a high-k material having a higher permittivity than silicon oxide. A high-k material may include hafnium oxide (HfO₂), zirconium oxide (ZrO₂), aluminum oxide (Al₂O₃), titanium oxide (TiO₂), tantalum oxide (Ta₂O₅), niobium (Nb₂O₅), or strontium titanium oxide (SrTiO₃). In another embodiment, the dielectric layer DE may be formed of a composite layer including two or more layers of the high-k materials mentioned above. In this embodiment, the dielectric layer DE may be formed of a zirconium oxide-based material having good leakage current characteristics while sufficiently lowering an equivalent oxide thickness (EOT). For example, the dielectric layer DE may include a stack of ZAZ (ZrO₂/Al₂O₃/ZrO₂). In another embodiment, the dielectric layer (DE) may include a stack of TiO₂/ZrO₂/Al₂O₃/ZrO₂, TiO₂/HfO₂/Al₂O₃/HfO₂, Ta₂O₅/ZrO₂/Al₂O₃/ZrO₂, or Ta₂O₅/HfO₂/Al₂O₃/HfO₂.

Next, a plate node TE may be formed on the dielectric layer DE. The plate node TE may fill a space between neighboring ones of the storage nodes SN. The plate node TE may extend to cover upper portions of the storage nodes SN. The plate node TE may include a conductive material. The plate node TE may be stacked in the order of a liner electrode, a gap fill electrode, and a low resistance electrode (reference numerals are omitted). The liner electrode of the plate node TE may include titanium nitride, and the gap fill electrode of the plate node TE may include silicon germanium. The low resistance electrode of the plate node TE may include tungsten or tungsten nitride.

Although the disclosure is shown and described with reference to specific embodiments thereof, the present disclosure is not limited thereto. It will readily be appreciated by one of ordinary skill in the art that various changes or modifications may be made thereto without departing from the scope of the disclosure.

What is claimed is:

1. A method for fabricating a semiconductor device, the method comprising:
forming an etch target layer on a substrate, wherein the etch target layer includes an alternating stack layer and a sacrificial stack layer on the alternating stack layer, and wherein the sacrificial stack layer includes the same material as the alternating stack layer;
forming a hard mask pattern on the sacrificial stack layer;
etching the etch target layer using the hard mask pattern as an etch barrier to form a plurality of initial high aspect ratio features, the initial high aspect ratio features penetrating through the etch target layer; and
removing the hard mask pattern and the sacrificial stack layer to form a plurality of high aspect ratio features.

2. The method according to claim 1,
wherein forming the alternating stack layer includes alternately stacking a plurality of insulating layers and a plurality of sacrificial layers, and
wherein the insulating layers and the sacrificial layers include different materials.

3. The method according to 2,
wherein forming the sacrificial stack layer includes alternately stacking a plurality of first sacrificial layers and a plurality of second sacrificial layers, wherein
the first sacrificial layers and the insulating layers are made of a same material, and
the second sacrificial layers and the sacrificial layers are made of a same material.

4. The method according to claim 3, wherein
the first sacrificial layers and the insulating layers include silicon oxide, and
the second sacrificial layers and the sacrificial layers include silicon nitride.

5. The method according to claim 1, wherein the etch target layer is alternately stacked with oxide layers and nitride layers,
wherein the alternating stack layer includes a greater number of oxide layers and nitride layers that are alternately stacked than in the sacrificial stack layer.

6. The method according to claim 1, wherein a thickness of the sacrificial stack layer is thinner than a thickness of the alternating stack layer.

7. The method according to claim 1, wherein the hard mask pattern includes a carbon-containing material.

8. The method according to claim 1, wherein the alternating stack layer and the sacrificial stack layer include silicon oxide, and the hard mask pattern includes amorphous carbon.

9. The method according to claim 1, wherein the alternating stack layer and the sacrificial stack layer include silicon nitride, and the hard mask pattern includes amorphous carbon.

10. A method for fabricating a semiconductor device, the method comprising:
forming an alternating stack layer by alternately stacking first oxide layers and first nitride layers on a substrate;
forming a sacrificial stack layer by alternately stacking second oxide layers and second nitride layers on the alternating stack;
forming an amorphous carbon layer pattern on the sacrificial stack layer;
etching the sacrificial stack layer and the alternating stack layer using the amorphous carbon layer pattern as an etch barrier to form a plurality of initial high aspect ratio features, the initial high aspect ratio features penetrating through the sacrificial stack layer and the alternating stack layer;
removing the amorphous carbon pattern and the sacrificial stack layer to form a plurality of high aspect ratio features;
forming a vertical channel structure filling the high aspect ratio features; and
replacing the first nitride layers of the alternating stack layer with gate electrodes.

11. The method according to claim 10, wherein the first oxide layers and the second oxide layers include silicon oxide.

12. The method according to claim 10, wherein the first nitride layers and the second nitride layers include silicon nitride.

13. The method according to claim 10, a number that the first oxide layers and the first nitride layers alternate is greater than a number that the second oxide layers and the second nitride layers alternate.

14. A hard mask for forming, through dry etching, a high aspect ratio in a stack film, in which first silicon oxides and first silicon nitrides are alternately stacked, the hard mask comprising:
a carbon-free hard mask, in which second silicon oxides and second silicon nitrides are alternately stacked; and
a carbon-containing hard mask on the carbon-free hard mask.

15. The hard mask of claim 14, wherein the carbon-containing hard mask includes amorphous carbon.

16. The hard mask of claim 14, wherein
each of the second silicon oxides is thinner than each of the first silicon oxides, and
each of the second silicon nitrides is thinner than each of the first silicon nitrides.

17. The hard mask of claim 14, wherein a number that the first silicon oxides and the first silicon nitrides alternate is greater than a number that the second silicon oxides and the second silicon nitrides alternate.

18. A method for fabricating a semiconductor device, the method comprising:
forming an etch stop layer on a substrate;
forming an alternating stack layer by alternately stacking first oxide layers and first nitride layers on the etch stop layer;
forming a sacrificial stack layer by alternately stacking second oxide layers and second nitride layers on the alternating stack layer;
forming an amorphous carbon layer pattern on the sacrificial stack layer;
etching the sacrificial stack layer and the alternating stack layer using the amorphous carbon layer pattern as an etch barrier to form a plurality of initial high aspect ratio features, the initial high aspect ratio features penetrating through the sacrificial stack layer and the alternating stack layer;
removing the amorphous carbon layer pattern and the sacrificial stack layer to form a plurality of high aspect ratio features;
forming a storage node in each of the high aspect ratio features;
forming a multi-level supporter by selectively etching the first nitride layers, the multi-level supporter supporting the storage node; and
removing the first nitride layers.

19. The method according to claim 18, wherein a number that the first oxide layers and the first nitride layers alternate is greater than a number that the second oxide layers and the second nitride layers alternate.
